(19) United States
(12) Patent Application Publication
(10) Pub. No.: US 2023/0217620 A1
(43) Pub. Date: Jul. 6, 2023

(54) Display Panel

(71) Applicant: LG Display Co., Ltd., Seoul (KR)

(72) Inventors: Jongseok Cha, Paju-si (KR); Dongwon Jang, Paju-si (KR)

(21) Appl. No.: 17/989,646

(22) Filed: Nov. 17, 2022

(30) Foreign Application Priority Data
Dec. 30, 2021 (KR) 10-2021-0192358

(51) Int. Cl. H05K 5/03; B32B 3/30; B32B 7/12

(52) U.S. Cl. CPC H05K 5/03; B32B 3/30; B32B 7/12; B32B 17/00

(57) ABSTRACT

The present disclosure relates to a display panel and particularly to a display panel including a backplate disposed below a panel layer and having a pattern forming area in which groove patterns are formed on both sides. Disclosed is a display panel including: a cover window including curved areas formed on both sides and a flat area formed in a middle; an adhesive layer disposed below the cover window; a panel layer disposed below the adhesive layer; and a backplate disposed below the panel layer and including pattern forming areas formed on both sides and a non-pattern area formed in a middle, and the backplate includes a plurality of groove patterns disposed in a first direction and extending in a second direction in the pattern forming area.

### CROSS REFERENCE TO RELATED APPLICATION

The present application claims priority to Korea Patent Application No. 10-2021-0192358, filed on Dec. 30, 2021, the entire contents of which is incorporated herein for all purposes by this reference.

### BACKGROUND

### Field

The present disclosure relates to a display panel and particularly to a display panel including a backplate disposed below a panel layer and having a pattern forming area in which groove patterns are formed on both sides.

### Description of the Related Art

As examples of a display device, a liquid crystal display (LCD), a field emission display device (FED), an electrowetting display Device (EWD) and an organic light emitting display device (OLED) are used.

Such a display device may include a cover window made of a glass or plastic material so as to protect a display panel from external shocks. An adhesive layer is applied below the cover window and through the adhesive layer, a polarizer or a panel layer is bonded to the cover window. Below the panel layer, a backplate is attached to reinforce rigidity of the panel layer.

In addition, the latest display devices employ a curved display that curves two surfaces on both sides of the cover window, or curves four surfaces, the left, right, top, and bottom surface, in order to improve grip feeling and widen a display area of a screen. Also, a curvature forming a curve tends to become larger at a user's request. In this case, a backplate disposed below the curved part of the cover window is being curved with the same curvature. Accordingly, a problem of a defect caused in the display panel occurs as huge stress is concentrated on the curved part of the backplate, and the backplate gets broken.

### SUMMARY

The present disclosure aims to solve such a problem, and to provide a display panel capable of relieving stress concentrated in a backplate, which is applied to a curved display.

One embodiment is a display panel including a cover window including curved areas formed on both sides and a flat area formed in a middle; an adhesive layer disposed below the cover window; a panel layer disposed below the adhesive layer; and a backplate disposed below the panel layer and including pattern forming areas formed on both sides and a non-pattern area formed in a middle, and the backplate includes a plurality of groove patterns disposed in a first direction and extending in a second direction in the pattern forming area.

Each of the plurality of groove patterns may include a groove pattern in a triangular shape.

The backplate has a first height, the groove pattern in a triangular shape has a second height, and the second height may be higher than a half of the first height.

A spacing between the groove patterns in a triangular shape may be equal to a half of the first height.

Each of the groove patterns in a triangular shape may be formed in a shape of a dotted line in the second direction.

Each of the plurality of groove patterns may include a semicircular shaped groove pattern.

The backplate has a first height, the semicircular shaped groove pattern has a second height, and the second height may be higher than a half of the first height.

A spacing between the semicircular shaped groove patterns may be longer than the second height and shorter than the first height.

Each of the semicircular shaped groove patterns may be formed in a shape of a dotted line in the second direction.

Each of the plurality of groove patterns may include a quadrangular shaped groove pattern.

The backplate has a first height, the quadrangular shaped groove pattern has a second height, and the second height may be higher than a half of the first height.

A spacing between the quadrangular shaped groove patterns may be longer than the second height and shorter than the first height.

A width of the quadrangular shaped groove pattern may be equal to or shorter than a half of the first height.

Each of the quadrangular shaped groove patterns may be formed in a shape of a dotted line in the second direction.

A width of the pattern forming area may be wider than a width of the curved area.

According to the present disclosure, it is possible to disperse stress of a backplate disposed on the curved display panel having curvature.

According to the present disclosure, it is possible to secure rigidity of a backplate disposed on the curved display panel having curvature.

According to the present disclosure, it is possible to compensate tolerance that may occur during bonding of the curved display panel having curvature.

### BRIEF DESCRIPTION OF THE DRAWINGS

FIG. 1 is a perspective view showing a cover window according to the present disclosure.

FIG. 2 is a side view showing a display panel according to the present disclosure.

FIG. 3 is a perspective view showing a backplate according to the present disclosure.

FIGS. 4 and 5 are a plan view and a cross-sectional view, respectively, of a part ‘A’ of FIG. 3 according to an embodiment of the present disclosure.

FIGS. 6 and 7 are drawings to explain a modified embodiment of the embodiment illustrated in FIG. 4.

FIGS. 8 and 9 are a plan view and a cross-sectional view, respectively, of a part ‘A’ of FIG. 3 according to another embodiment of the present disclosure.

FIGS. 10 and 11 are drawings to explain a modified embodiment of the embodiment illustrated in FIG. 8.

FIGS. 12 and 13 are a plan view and a cross-sectional view, respectively, of a part ‘A’ of FIG. 3 according to still another embodiment of the present disclosure.

FIGS. 14 and 15 are drawings to explain a modified embodiment of the embodiment illustrated in FIG. 12.

### DETAILED DESCRIPTION

Hereinafter, various embodiments will be explained with reference to drawings. When an element (or an area, a layer, a part and the like) is ‘on’ another element, is ‘connected’ with, or ‘coupled’ to another element, the element may be directly connected with or coupled to another element or a third intervening element may be disposed therebetween.

Like reference numerals of the accompanying drawings denote like elements. In addition, thicknesses, proportions and dimensions of the elements in the accompanying drawings are exaggerated for convenience of describing the technical contents. The term “and/or” includes any and all combinations of one or more of the associated listed items.

Though terms such as ‘a first’, or ‘a second’ are used to describe various components, these components are not confined by these terms. These terms are merely used to distinguish one component from the other component. For example, without departing from the scope of the rights of various embodiments of the present invention, a first component may be referred to as a second component, and similarly, a second component may be referred to as a first component. The singular forms expressed herein are intended to include the plural forms as well, unless the context expressly indicates otherwise.

Terms such as ‘below’, ‘at a lower portion’, ‘on’, ‘at an upper portion’ and the like are used to describe position relation of parts illustrated in the accompanying drawings. Such terms are of relative concept, and are explained based on the directions marked in the drawings.

It should be understood that terms such as ‘comprise’, or ‘have’ and the like are used only to designate that there are features, numbers, steps, operations, components, parts or combination thereof, however such terms do not preclude existence or addition of one or more another features, numbers, steps, operations, components, parts or combination thereof.

In addition, the present disclosure explains an organic light emitting display panel as an example for convenience of description. However, the idea of the present disclosure is not limited to the organic light emitting display panel, and may be applied in the same way to other types of display panel such as a liquid crystal display panel, a mini-LED display panel and the like.

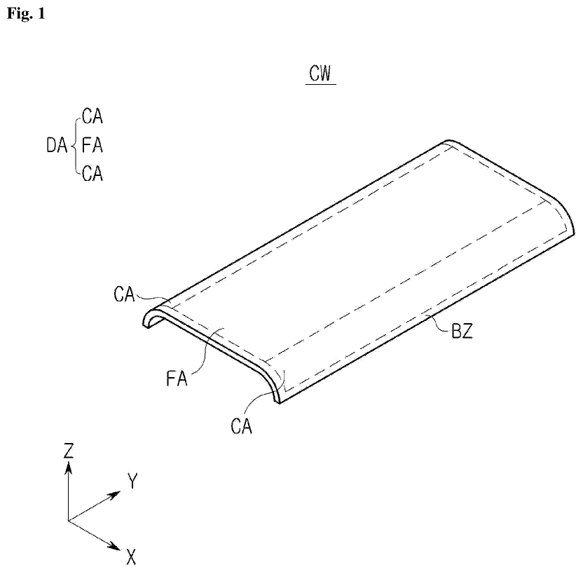

FIG. 1 is a perspective view showing a cover window according to the present disclosure.

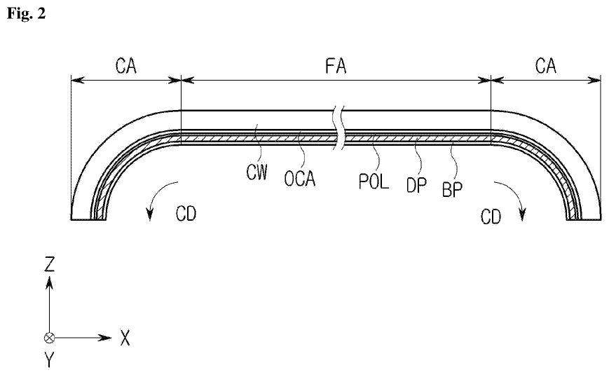

FIG. 2 is a side view showing a display panel according to the present disclosure.

With reference to FIGS. 1 and 2, the cover window and the display panel according to the present disclosure will be explained.

The cover window (CW) according to the present disclosure may include a display area (DA) having features of displaying an image and touch sensing, and a bezel area (BZ) positioning at an outer region adjacent to the display area (DA). The bezel area (BZ) may be disposed to wrap the display area (DA).

The display area (DA) may be an area where a plurality of pixels to display an image and a plurality of touch sensors for touch sensing are disposed. The display area (DA) may be referred to as an active area, a pixel matrix area or a touch sensing area. The bezel area (BZ) may be an area where a plurality of wirings and a plurality of pads are disposed. The bezel area (BZ) may be referred to as a non-active area, non-pixel area or a touch non-sensing area.

On the cover window (CW), curved areas (CA) may be formed on both sides thereof, and a flat area (FA) may be formed in the middle. A curved area (CA) is an area formed both on the left side and the right side of the cover window, and is formed in a way the cover window (CW) is curved towards a bottom direction. The cover window (CW) formed to have curves as above may provide an excellent grip feeling to a user. As illustrated in FIG. 2, a curve direction (CD) where a curved area (CA) is formed may be a direction opposite (−Z direction) of the direction towards the outside of the display device (Z direction). Such a cover window (CW) may be formed of a glass material or a plastic material, and may be formed of a transparent material. As illustrated in FIG. 1, the display area (DA) may include the curved area (CA) and the flat area (FA). In other words, pixels are disposed in the curved area (CA) as well as in the flat area (FA), and thus, a screen may be displayed in the curved area (CA), too.

Referring to FIG. 2, an adhesive layer (OCA), a polarizer (POL), a panel layer (DP) and a backplate (BP) may be disposed below the cover window (CW).

The adhesive layer (OCA) may be disposed below the cover window (CW) and serve to adhere the cover window (CW) to the polarizer (POL). The adhesive layer (OCA), for example, may be an optical clear adhesive (OCA), but is not limited thereto. For example, the adhesive layer (OCA) may be formed of a material such as a pressure sensitive adhesive (PSA). The adhesive layer (OCA) may be of a transparent material.

The polarizer (POL) may be formed of a film having a polarization feature. The polarizer (POL) may suppress reflection of external light and may reduce reflection feeling when viewed outside.

The panel layer (DP) may be a layer where pixels are formed, a gate electrode, a source electrode, a drain electrode and a transistor including a semiconductor layer and the like are formed inside. Also, the panel layer (DP) may be a layer where light emitting diodes such as an anode electrode, a light emitting layer and a cathode electrode are formed. The panel layer (DP) may include an organic light emitting material, a liquid crystal layer and a micro-LED and the like.

The backplate (BP) may maintain rigidity of the panel layer (DP) and prevent attachment of a foreign substance below the panel layer (DP). Further, the backplate (BP) may serve to absorb external shocks. The backplate (BP) may be implemented as a plastic thin film formed of polyimide.

The adhesive layer (OCA), the polarizer (POL), the panel layer (DP) and the backplate (BP) mentioned above may be formed in the curved area (CA) as well as in the flat area (FA). In other words, a screen may be displayed in the curved area (CA) as well because the panel layer (DP) is disposed in the curved area (CA).

In such a case, stress is given to the backplate (BP) due to curving. In other words, since the backplate (BP) is a configuration to reinforce rigidity of the panel layer (DP), the backplate (BP) is formed of a material having higher rigidity such as plastic or metal, and when the backplate (BP) is being curved to form the curved area (CA), stress may occur due to the curving. Such stress may break the backplate (BP), and the display panel may become defective.

According to the present disclosure, the backplate (BP) may include a pattern area where a pattern is formed at a position corresponding to the curved area (CA). Such a pattern area may relieve stress concentration that may occur in the curved area (CA) of the backplate (BP).

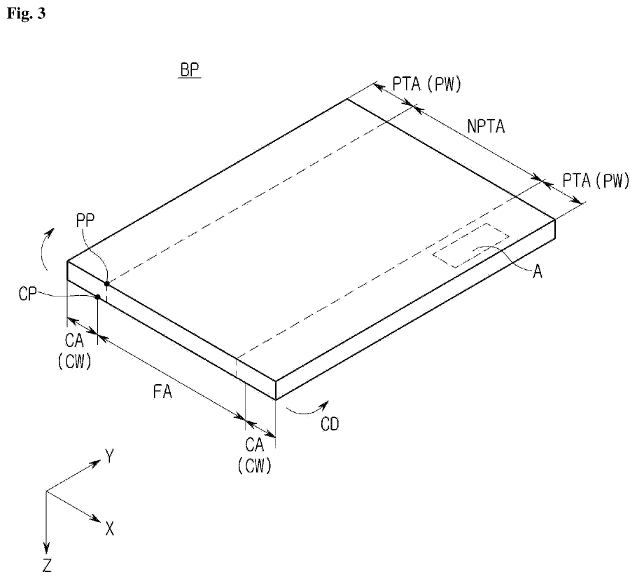

FIG. 3 is a perspective view showing a backplate according to an embodiment of the present disclosure.

Referring to FIG. 3, the backplate (BP) is illustrated.

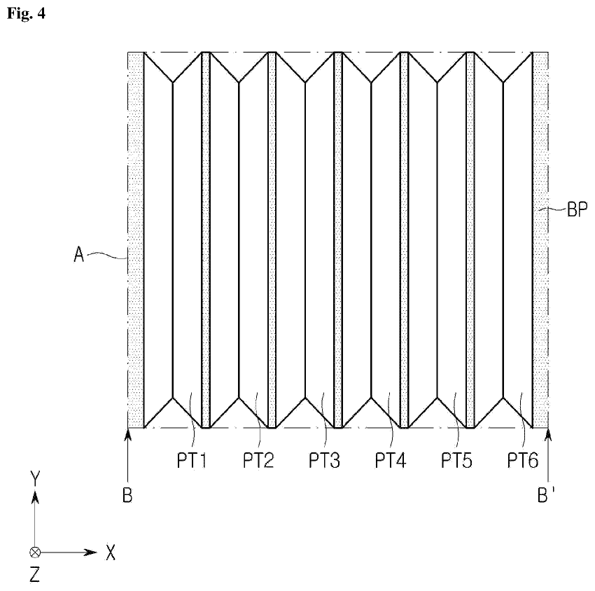

Specifically, the backplate (BP) may include a pattern forming area (PTA) formed on both sides and a non-pattern area (NPTA) formed in the middle. A shape of a pattern formed in the pattern forming area (PTA) will be explained later on with reference to FIGS. 4 to 9, which are enlarged views of part ‘A’ marked in FIG. 3.

In the pattern forming area (PTA), a pattern may be formed on a rear surface of the backplate (BP). The rear surface may refer to a surface located in the same direction as a curve direction (CD) in which the backplate (BP) is curved. Based on FIG. 3, the rear surface of the backplate (BP) may refer to a minus Z (−Z) axis direction. The pattern formed in the pattern forming area (PTA) of the backplate (BP) may be a plurality of groove patterns. The plurality of groove patterns may be patterns that are arranged in the first direction and extend in the second direction. The first direction may be X axis direction, based on FIG. 3. The second direction may be Y axis direction, based on FIG. 3.

A width (PW) of the pattern forming area (PTA) may not be equal to a width (CW) of the curved area (CA). For example, as illustrated in FIG. 3, the width (PW) of the pattern forming area (PTA) may be wider than the width (CW) of the curved area (CA). For example, the width (PW) of the pattern forming area (PTA) may be wider by 0.5 mm than the width (CW) of the curved area (CA).

Such a tolerance between widths (PW, CW) may be the tolerance considering an error in a bonding process. Specifically, during the bonding process which bonds the cover window (CW) and configurations (POL, DP, BP) below the cover window (CW), an error may take place in the first direction (X axis direction). Considering the error that may arise during the process, the present disclosure may make a starting point (PP) of the pattern forming area (PTA) protrude further inward by a predetermined length, compared with the starting point (CP) of the curved area (CA). Here, the term ‘inward’ refers to a direction towards a center of the backplate (BP), and may be a direction towards a flat area (FA) from the curved area (CA), based on FIG. 3. Or, the term ‘inward’ may refer to a direction from the pattern forming area (PTA) towards the non-pattern area (NPTA), based on FIG. 3.

With reference to FIGS. 4 to 15, a detailed shape of the pattern according to the present disclosure will be explained.

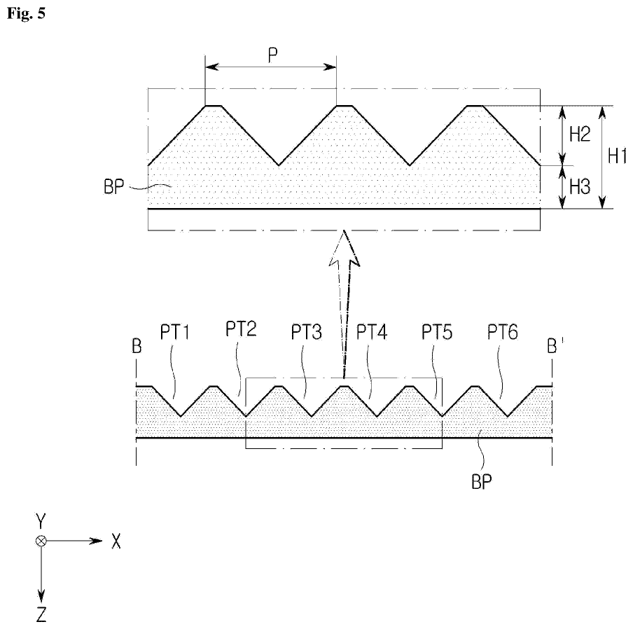

FIGS. 4 and 5 are a plan view and a cross-sectional view, respectively, of a part ‘A’ of FIG. 3 according to an embodiment of the present disclosure.

With reference to FIGS. 4 and 5, a plan view and a cross-sectional view of a part ‘A’ of FIG. 3, which is a portion of the pattern forming area (PTA), are illustrated.

According to the embodiment, each of the plurality of groove patterns may include the groove pattern (PT1 to PT6) in a triangular shape.

Specifically, the triangular shaped groove pattern (PT1 to PT6) may take a form of a triangle which is cut downwardly in an XZ plane on an upper surface of the backplate (BP), as illustrated in a cross-sectional view taken in B-B′ direction.

Such a groove pattern (PT1 to PT6) may be arranged in the first direction (X). In addition, the groove pattern (PT1 to PT6) may be formed to extend in the second direction (Y). That is, each of the groove patterns (PT1 to PT6) may be integrally formed in the whole portion of the second direction (Y) in the pattern forming area (PTA).

The backplate (BP) may have the first height (H1) and the triangular shaped groove pattern (PT1 to PT6) may have the second height (H2). For the purpose of taking an example, the first height (H1) may be 88 μm and the second height (H2) may be 48 μm. That is, the second height (H2) of the triangular shaped groove pattern (PT1 to PT6) may be higher than a half (½) of the first height (H1) of the backplate (BP) according to the present embodiment. By forming the height (H2) of the groove pattern higher than a half of the height (H1) of the backplate, stress concentrated in the backplate (BP) may be relieved. In contrast, when forming the height (H2) of the groove pattern lower than a half of the height (H1) of the backplate, there may be a problem of stress uneased in the backplate being curved.

In the pattern forming area (PTA) of the backplate (BP), a third height (H3) belonged to a part where the triangular shaped groove pattern (PT1 to PT6) is not formed may be a height obtained by subtracting the second height (H2) from the first height (H1). For example, when the first height (H1) is 88 μm and the second height (H2) is 48 μm, the third height (H3) may be 40 μm. Such a third height (H3) may be a height to secure the minimum rigidity of the backplate (BP). In contrast, when forming the third height (H3) of a part where the groove pattern (PT1 to PT6) is not formed shorter, there may be a problem in that the backplate (BP) may be broken or have a crack in the curved area.

Each of the plurality of triangular shaped groove pattern (PT1 to PT6) being formed in the pattern forming area (PTA) of the backplate (BP) may be arranged along the first direction (X) with a uniform distance (P) therebetween. The distance (P) may be equal to a half of the first height (H1). For example, assuming that the first height (H1) is 88 μm, the distance (P) between the groove patterns (PT1 to PT6) may be 44 μm. By making the distance (P) between the groove patterns be equal to a half of the height (H1) of the backplate, it becomes possible to relieve stress concentration in the backplate (BP). In contrast, when forming the distance (P) between the groove patterns (PT1 to PT6) longer than a half of the first height (H1), a problem may occur that stress concentration in the backplate (BP) may not be dispersed well. To the contrary, when forming the distance (P) between the groove patterns (PT1 to PT6) shorter than a half of the first height (H1), a problem may occur in that the backplate (BP) may be broken or have a crack in the curved area.

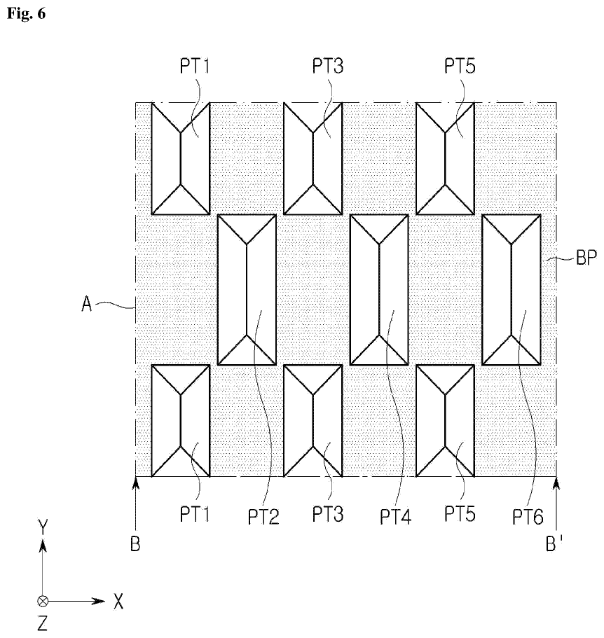

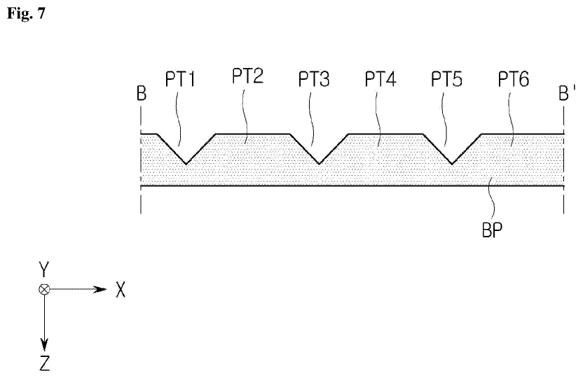

FIGS. 6 and 7 are drawings to explain a modified embodiment of the embodiment illustrated in FIG. 4.

Referring to FIGS. 6 and 7, the plurality of groove patterns (PT1 to PT6) are illustrated, and each of the groove patterns (PT1 to PT6) may be formed in a shape of a dotted line in the second direction (Y).

Specifically, a plurality of groove patterns (PT1 to PT6) may be groove patterns (PT1 to PT6) in a triangular shape as described with reference to FIG. 4. The triangular shaped groove patterns (PT1 to PT6) may be in a triangular shape in the XZ plane and a shape cut downwardly from the upper surface of the backplate (BP), as illustrated in a cross-sectional view taken in B-B′ direction.

In the embodiment explained with reference to FIGS. 4 and 5, the triangular shaped groove patterns (PT1 to PT6) are integrally formed in the whole portion of the second direction (Y). In the embodiment explained with reference to FIGS. 6 and 7, the triangular shaped groove patterns (PT1 to PT6) may be formed in a dotted line shape in the second direction (Y).

Specifically, with reference to the first pattern (PT1), the first pattern (PT1) extends in the second direction (Y) however, the pattern may not be formed in some part while being extended. The second pattern (PT2), too, is a pattern extending in the second direction (Y), however, the pattern may not be formed in some part while being extended. As illustrated in the cross section taken in B-B′ direction, the first pattern (PT1) takes the form of a triangle, and takes the form where the backplate (BP) is cut in a height direction. The second pattern (PT2) takes the form where the backplate (BP) is the same in a height direction since the pattern is not formed. Such a form of a dotted line may be repeated in the third pattern (PT3) and the fourth pattern (PT4).

In the present embodiment, by making the triangular shaped groove patterns (PT1 to PT6) take a dotted line shape, rigidity of the backplate (BP) may be maintained to be the same, and stress occurring by a curve may be relieved.

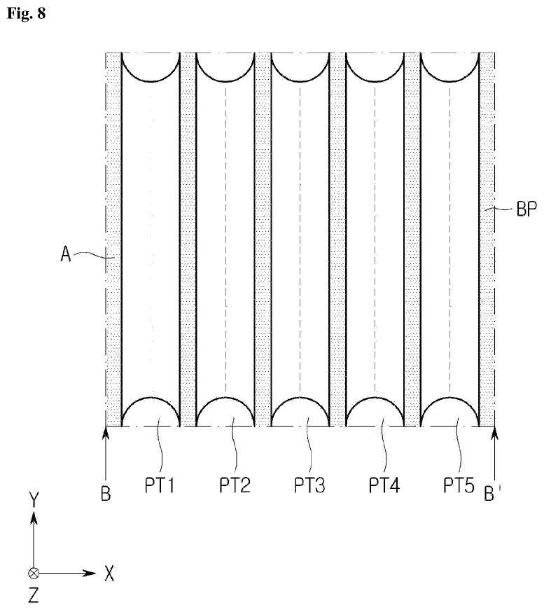

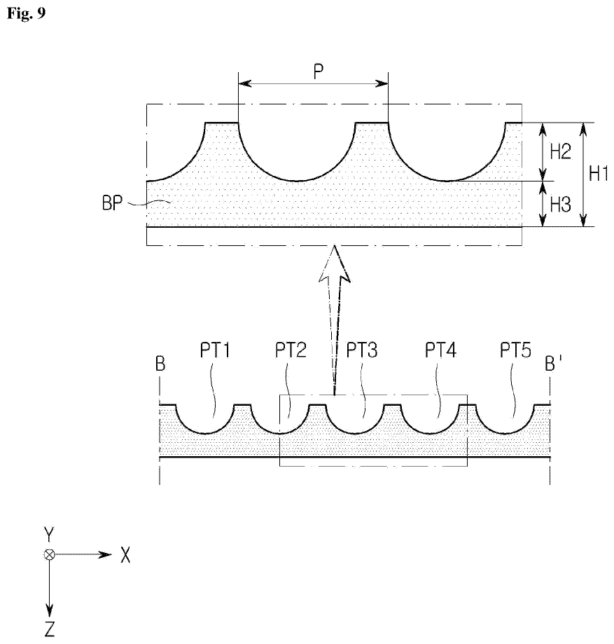

FIGS. 8 and 9 are a plan view and a cross-sectional view, respectively, of a part ‘A’ of FIG. 3 according to another embodiment of the present disclosure.

Referring to FIGS. 8 and 9, a plan view and a cross-sectional view of a part ‘A’ of FIG. 3, which is a portion of the pattern forming area (PTA) of FIG. 3, are illustrated.

According to the embodiment, each of the plurality of groove patterns may include a semicircular shaped groove pattern (PT1 to PT5).

Specifically, the semicircular shaped groove patterns (PT1 to PT5) may be in a semicircular form in the XZ plane which is cut downwardly from the upper surface of the backplate (BP), as illustrated in a cross-sectional view taken in a B-B′ direction.

Such a groove pattern (PT1 to PT5) may be arranged in the first direction (X). In addition, the groove pattern (PT1 to PT5) may be formed to extend in the second direction (Y). In other words, each of the groove patterns (PT1 to PT5) may be integrally formed in the whole portion of the second direction (Y) in the pattern forming area (PTA).

The backplate (BP) may have the first height (H1), and the semicircular shaped groove pattern (PT1 to PT5) may have the second height (H2). For the purpose of taking an example, the first height (H1) may be 88 μm, and the second height (H2) may be 48 μm. In short, according to the embodiment, the second height (H2) of the semicircular shaped groove pattern (PT1 to PT5) may be higher than a half (½) of the first height (H1) of the backplate (BP). By forming the height (H2) of the groove pattern higher than a half of the height (H1) of the backplate, it becomes possible to relieve stress concentrated in the backplate (BP). In contrast, when forming the height (H2) of the groove pattern lower than a half of the height (H1) of the backplate, a problem may occur in that the stress of the curved backplate (BP) may not be relieved.

In the pattern forming area (PTA) of the backplate (BP), the third height (H3) belonged to a part where the semicircular shaped groove pattern (PT1 to PT5) is not formed may be a height obtained by subtracting the second height (H2) from the first height (H1). For example, when the first height (H1) is 88 μm and the second height (H2) is 48 μm, the third height (H3) may be 40 μm. Such a third height (H3) may be the height to secure the minimum rigidity of the backplate (BP). In contrast, when forming the third height (H3) of which the groove pattern (PT1 to PT5) is not formed to be lower, there may be a problem in that the backplate (BP) may be broken or have a crack in the curved area.

Each of the plurality of semicircular shaped groove pattern (PT1 to PT5) formed in the pattern forming area (PTA) of the backplate (BP) may be disposed with a uniform distance (P) along the first direction (X). The distance (P) may be longer than the second height (H2) and shorter than the first height (H1). For example, when the first height (H1) is 88 μm, and the second height is 48 μm, the distance (P) between the groove patterns (PT1 to PT5) may be 74 μm. By forming the distance (P) between the groove patterns longer than the second height (H2) and shorter than the first height (H1), it becomes possible to relieve stress concentrated in the backplate (BP). In contrast, when forming the distance (P) between the groove patterns (PT1 to PT5) longer than the first height (H1), there may be a problem in that the stress concentrated in the backplate (BP) may not be dispersed properly. To the contrary, when forming the distance (P) between the groove patterns (PT1 to PT5) shorter than the second height (H2), there may be a problem in that the backplate (BP) may be broken or have a crack in the curved area.

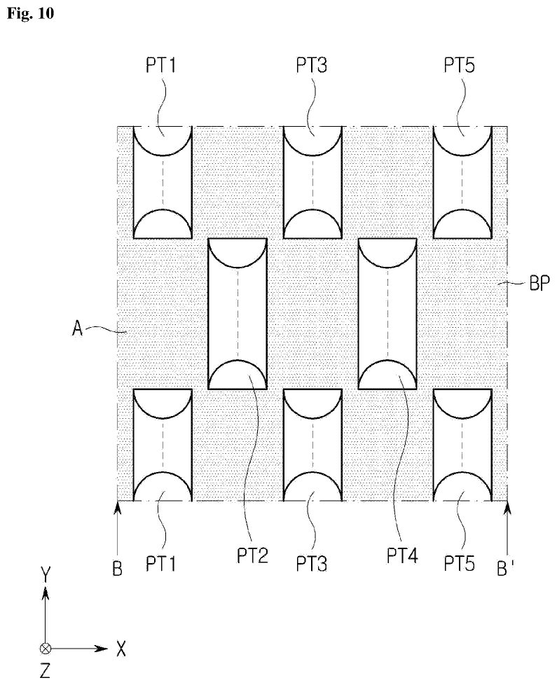

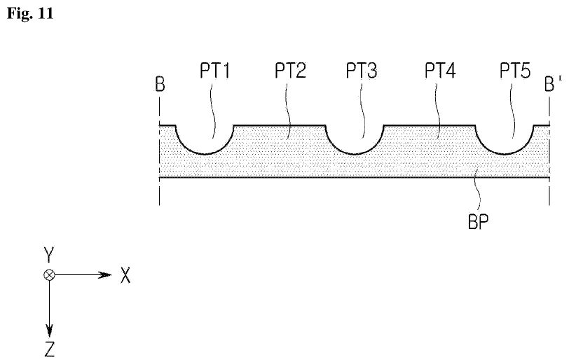

FIGS. 10 and 11 are drawings to explain a modified embodiment of the embodiment illustrated in FIG. 8.

Referring to FIGS. 10 and 11, a plurality of groove patterns (PT1 to PT5) are illustrated, and each of the groove patterns (PT1 to PT5) may be formed in a shape of a dotted line in the second direction (Y).

Specifically, a plurality of groove patterns (PT1 to PT5) may be the semicircular shaped groove patterns (PT1 to PT5) as explained in FIGS. 8 and 9. The semicircular shaped groove pattern (PT1 to PT5) may take a form of a semicircle which is cut downwardly in the XZ plane on an upper surface of the backplate (BP), as illustrated in a cross-sectional view taken in B-B′ direction.

In the embodiment previously explained with refence to FIGS. 8 and 9, the semicircular shaped groove pattern (PT1 to PT5) is integrally formed in the whole portion of the second direction (Y). In the embodiment previously explained with refence to FIGS. 10 and 11, the semicircular shaped groove pattern (PT1 to PT5) may be formed in a shape of a dotted line in the second direction (Y)

Specifically, referring to the first pattern (PT1), the first pattern (PT1) is the one that extends in the second direction (Y); however, the pattern may not be formed in some part while being extended. The second pattern (PT2), too, is a pattern extending in the second direction (Y), however, the pattern may not be formed in some part while being extended. As illustrated in the cross section taken in B-B′ direction, the first pattern (PT1) takes the form of a semicircle, and takes the form where the backplate (BP) is cut in a height direction. The second pattern (PT2) takes the form where the backplate (BP) is the same in a height direction since the pattern is not formed. Such a form of a dotted line may be repeated in the third pattern (PT3) and the fourth pattern (PT4).

In the present embodiment, by making the semicircular shaped groove patterns (PT1 to PT5) take a dotted line shape, rigidity of the backplate (BP) may be maintained to be the same, and stress occurring by a curve may be relieved.

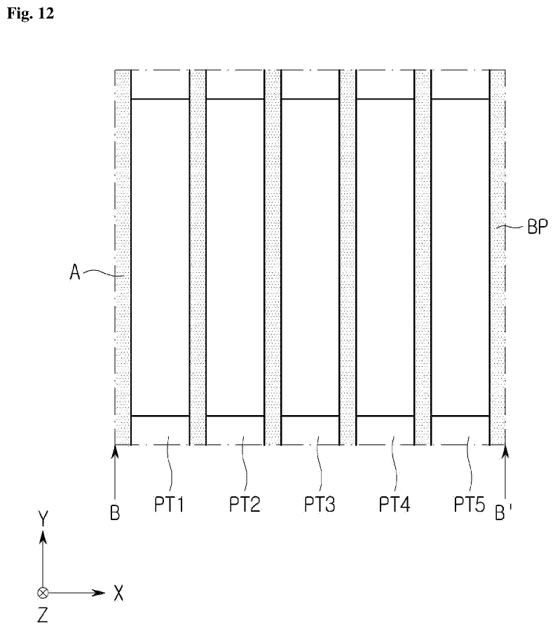

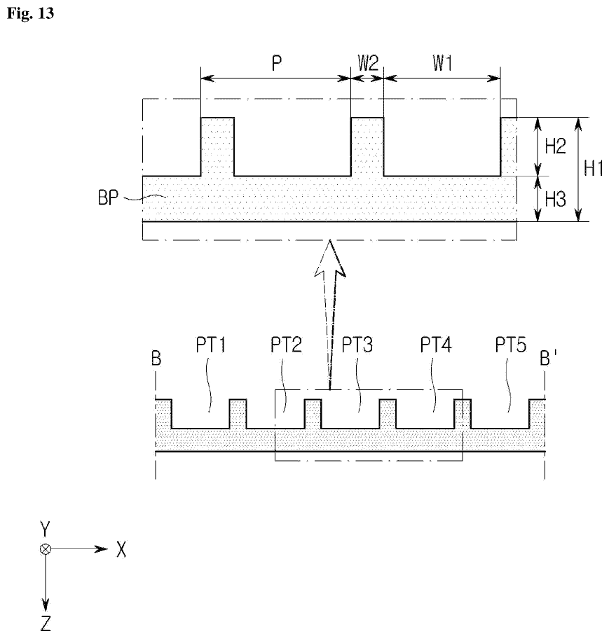

FIGS. 12 and 13 are a plan view and a cross-sectional view, respectively, of a part ‘A’ of FIG. 3 according to still another embodiment of the present disclosure.

In FIGS. 12 and 13, a plan view and a cross-sectional view of a part ‘A’ of FIG. 3, which is a portion of the pattern forming area (PTA) of FIG. 3 are illustrated.

According to the embodiment, each of a plurality of groove patterns may include a quadrangular groove pattern (PT1 to PT5).

Specifically, the quadrangular groove pattern (PT1 to PT5) may be in a quadrangular form in the XZ plane, and cut downwardly from the upper surface of the backplate (BP), as illustrated in a cross-sectional view taken in a B-B′ direction.

Such a groove pattern (PT1 to PT5) may be arranged in the first direction (X). In addition, the groove pattern (PT1 to PT5) may be formed to extend in the second direction (Y). In other words, each of the groove patterns (PT1 to PT5) may be integrally formed in the whole portion of the second direction (Y) within the pattern forming area (PTA).

The backplate (BP) may have the first height (H1), and the quadrangular shaped groove pattern (PT1 to PT5) may have the second height (H2). For the purpose of taking an example, the first height (H1) may be 88 μm, and the second height (H2) may be 48 μm. In short, according to the embodiment, the second height (H2) of the quadrangular shaped groove pattern (PT1 to PT5) may be higher than a half (½) of the first height (H1) of the backplate (BP). By forming the height (H2) of the groove pattern higher than a half of the height (H1) of the backplate, it becomes possible to relieve stress concentrated in the backplate (BP). In contrast, when forming the height (H2) of the groove pattern lower than a half of the height (H1) of the backplate, a problem may occur in that the stress of the curved backplate (BP) may not be relieved.

In the pattern forming area (PTA) of the backplate (BP), the third height (H3) belonged to a part where the quadrangular shaped groove pattern (PT1 to PT5) is not formed may be a height obtained by subtracting the second height (H2) from the first height (H1). For example, when the first height (H1) is 88 μm and the second height (H2) is 48 μm, the third height (H3) may be 40 μm. Such a third height (H3) may be the height to secure the minimum rigidity of the backplate (BP). In contrast, when forming the third height (H3) of which the groove pattern (PT1 to PT5) is not formed to be lower, there may be a problem in that the backplate (BP) may be broken or have a crack in the curved area.

Each of the plurality of quadrangular shaped groove pattern (PT1 to PT5) formed in the pattern forming area (PTA) of the backplate (BP) may be disposed with a uniform distance (P) along the first direction (X). The distance (P) may be longer than the second height (H2) and shorter than the first height (H1). For example, when the first height (H1) is 88 μm, and the second height is 48 μm, the distance (P) between the groove patterns (PT1 to PT5) may be 74 μm. By forming the distance (P) between the groove patterns longer than the second height (H2) and shorter than the first height (H1), it becomes possible to relieve stress concentrated in the backplate (BP). In contrast, when forming the distance (P) between the groove patterns (PT1 to PT5) longer than the first height (H1), there may be a problem in that the stress concentrated in the backplate (BP) may not be dispersed properly. To the contrary, when forming the distance (P) between the groove patterns (PT1 to PT5) shorter than the second height (H2), there may be a problem in that the backplate (BP) may be broken or have a crack in the curved area.

In the pattern forming area (PTA) of the backplate (BP), a width (W2) of a part of which a quadrangular shaped groove pattern (PT1 to PT5) is not formed may be equal to, or less than a half of the first height (H1). For example, when the first height (H1) is 88 μm, the width (W2) of a part of which the quadrangular shaped groove pattern (PT1 to PT5) is not formed may be 30 μm. This may be to secure a width to implement straight lines forming a square, since the groove pattern (PT1 to PT5) of the embodiment takes the form of a square. Further, the width (W2) may be to secure sufficient groove patterns so as to relieve the stress of the backplate (BP). In contrast, when forming the width (W2) of the part of which a quadrangular shaped groove pattern (PT1 to PT5) is not formed to be longer than the first height (H1), there may be a problem in that the backplate (BP) may be broken or have a crack in the curved area.

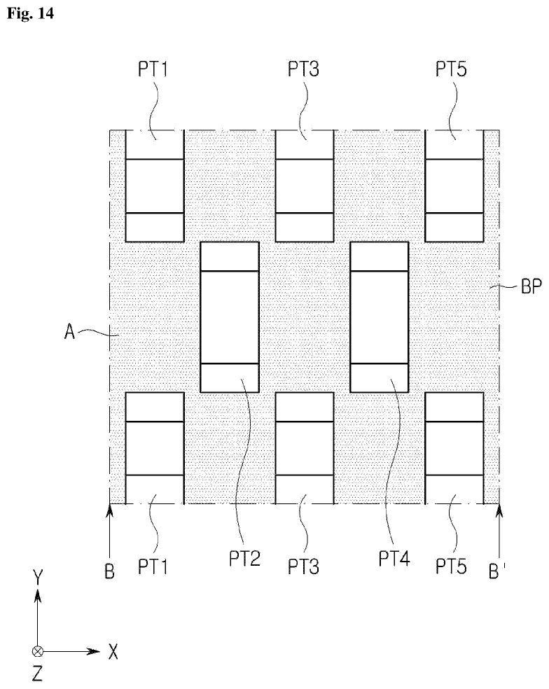

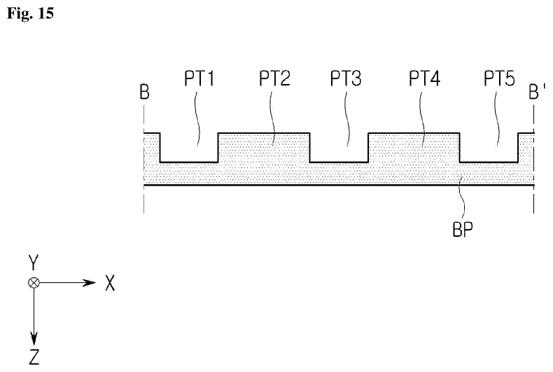

FIGS. 14 and 15 are drawings to explain a modified embodiment of the embodiment illustrated in FIG. 12.

Referring to FIGS. 14 and 15, a plurality of groove patterns (PT1 to PT5) are illustrated, and each of the groove patterns (PT1 to PT5) may be formed in a shape of a dotted line in the second direction (Y).

Specifically, the plurality of groove patterns (PT1 to PT5) may be the quadrangular shaped groove patterns (PT1 to PT5) as explained in FIGS. 12 and 13. The quadrangular shaped groove pattern (PT1 to PT5) may take a form of a square which is cut downwardly in the XZ plane on an upper surface of the backplate (BP), as illustrated in a cross-sectional view taken in B-B′ direction.

In the embodiment explained with reference to FIGS. 12 and 13, the quadrangular shaped groove patterns (PT1 to PT5) are integrally formed in the whole portion of the second direction (Y). In the embodiment explained with reference to FIGS. 14 and 15, the quadrangular shaped groove patterns (PT1 to PT5) may be formed in a shape of a dotted line in the second direction (Y).

Specifically, with reference to the first pattern (PT1), the first pattern (PT1) extends in the second direction (Y) however, the pattern may not be formed in some part while being extended. The second pattern (PT2), too, is a pattern extending in the second direction (Y), however, the pattern may not be formed in some part while being extended. As illustrated in the cross section taken in B-B′ direction, the first pattern (PT1) takes the form of a square, and takes the form where the backplate (BP) is cut in a height direction. The second pattern (PT2) takes the form where the backplate (BP) is the same in the height direction since the pattern is not formed. Such a form of a dotted line may be repeated in the third pattern (PT3) and the fourth pattern (PT4).

In the present embodiment, by making the quadrangular shaped groove patterns (PT1 to PT5) take a dotted line shape, rigidity of the backplate (BP) may be maintained to be the same, and stress occurring by the curve may be relieved.

Those skilled in the art may understand that the present disclosure described herein may be implemented in other concrete forms without departing from the technical concept or essential features thereof. Thus, it should be understood that embodiments described hereinabove are examples in all aspects, and do not limit the present disclosure. The scope of the present disclosure will be denoted by the claims that are provided hereinbelow, rather than the detailed description. In addition, it should be construed that all modifications or variations that are derived from the meaning, scope and the concept of equivalence of the claims are covered in the scope of the present disclosure.

### REFERENCE NUMERALS

CW: COVER WINDOW
OCA: ADHESIVE LAYER
POL: POLARIZER
DP: PANEL LAYER
BP: BACKPLATE
CA: CURVED AREA
FA: FLAT AREA
DA: DISPLAY AREA
PTA: PATTERN FORMING AREA
NPTA: NON-PATTERN AREA
CD: CURVE DIRECTION
PT1˜PT6: GROOVE PATTERN

What is claimed is:

1. A display panel comprising:
a cover window comprising curved areas formed on both sides and a flat area formed in a middle;
an adhesive layer disposed below the cover window;
a panel layer disposed below the adhesive layer; and
a backplate disposed below the panel layer and comprising pattern forming areas formed on both sides and a non-pattern area formed in a middle,
wherein the backplate comprises a plurality of groove patterns disposed in a first direction and extending in a second direction in the pattern forming area.

2. The display panel of claim 1,
wherein each of the plurality of groove patterns comprises a groove pattern in a triangular shape.

3. The display panel of claim 2,
wherein the backplate has a first height,
wherein the groove pattern in a triangular shape has a second height, and
wherein the second height is greater than a half of the first height.

4. The display panel of claim 3,
wherein a spacing between the groove patterns in a triangular shape is equal to a half of the first height.

5. The display panel of claim 2,
wherein each of the groove patterns in a triangular shape is formed in a shape of a dotted line in the second direction.

6. The display panel of claim 1,
wherein each of the plurality of groove patterns comprises a semicircular shaped groove pattern.

7. The display panel of claim 6,
wherein the backplate has a first height,
wherein the semicircular shaped groove pattern has a second height, and
wherein the second height is greater than a half of the first height.

8. The display panel of claim 7,
wherein a spacing between the semicircular shaped groove patterns is longer than the second height and shorter than the first height.

9. The display panel of claim 6,
wherein each of the semicircular shaped groove patterns is formed in a shape of a dotted line in the second direction.

10. The display panel of claim 1,
wherein each of the plurality of groove patterns comprises a quadrangular shaped groove pattern.

11. The display panel of claim 10,
wherein the backplate has a first height,
wherein the quadrangular shaped groove pattern has a second height, and
wherein the second height is greater than a half of the first height.

12. The display panel of claim 11,
wherein a spacing between the quadrangular shaped groove patterns is longer than the second height and shorter than the first height.

13. The display panel of claim 12,
wherein a width of the quadrangular shaped groove pattern is equal to or shorter than a half of the first height.

14. The display panel of claim 10,
wherein each of the quadrangular shaped groove patterns is formed in a shape of a dotted line in the second direction.

15. The display panel of claim 1,
wherein a width of the pattern forming area is greater than a width of the curved area.
